(19) United States
(12) Patent Application Publication
(10) Pub. No.: US 2014/0252510 A1
(43) Pub. Date: Sep. 11, 2014

(54) SIGNAL BOOSTING APPARATUS AND METHOD OF BOOSTING SIGNALS

(71) Applicant: SenseTech Co., Ltd, Taipei City (TW)

(72) Inventors: Mao-Chen LIU, Nantou County (TW); Po-Wei LU, Bade City, Taoyuan County (TW); Wen-Chieh CHOU, Taoyuan County (TW); Shu-Yi WENG, Miaoli County (TW); Chun-Chieh WANG, Taichung City (TW)

(73) Assignee: SenseTech Co., Ltd, Taipei City (TW)

(21) Appl. No.: 14/200,735

(22) Filed: Mar. 7, 2014

(30) Foreign Application Priority Data
Mar. 8, 2013 (TW) 102108324

(51) Int. Cl. B81B 7/02; B81C 1/00

(52) U.S. Cl. CPC B81B 7/02; B81C 1/00698
USPC 257/415; 438/52

(57) ABSTRACT

A signal boosting apparatus and a method of boosting signals applied in the MEMS are disclosed. The signal boosting apparatus includes a substrate, an oxide layer, and a signal transmission layer. The substrate has a doped region. The doped region has a plurality of conductive carriers. These conductive carriers have the same polarity as an electronic signal. The oxide layer is located on the substrate, and the signal transmission layer is located on the oxide layer. The signal transmission layer can receive and boost the electronic signal.

### CROSS-REFERENCE TO RELATED APPLICATIONS

This non-provisional application claims priority under 35 U.S.C. §119(a) on Patent Application No(s). 102108324 filed in Taiwan, R.O.C. on Mar. 8, 2013, the entire contents of which are hereby incorporated by reference.

### TECHNICAL FIELD

The disclosure relates to a signal boosting apparatus and a method of boosting signals, and more particularly to a signal boosting apparatus and a method of boosting signals, which are adapted to a micro-electromechanical apparatus and are capable of preventing an electronic signal from signal loss.

### BACKGROUND

For the semiconductor fabrication of semiconductor devices, metal layers and oxide layers are very commonly used. Take a micro-electromechanical system (MEMS) device as an example. The MEMS device usually has metal layers and oxide layers layered and can integrate an application-specific integrated circuit (ASIC) and a MEMS together in the same surface, thereby simplifying its packaging process. However, between the MEMS device and the material of its peripheral structure the parasitic effect exists.

To produce a MEMS device, its mechanical structure has to be transformed to an equivalent circuit, and then this equivalent circuit will be integrated with the ASIC to produce a system-on-chip (SoC). However, most MEMS devices usually are constructed on silicon substrates. When electronic signals are transmitted in the MEMS device, parasitic capacitors may be formed between the MEMS device and the silicon substrate. Therefore, a part of the electronic signal may flow in the silicon substrate and become lost. In other words, such parasitic capacitors may reduce the intensity of the electronic signal traveling in the MEMS device, that is, reduce the output power of the electronic signal. Moreover, such parasitic capacitors may complicate the design of a next stage of signal processing circuits.

### SUMMARY

According to one or more embodiments, the disclosure provides a signal boosting apparatus adapted to a micro-electromechanical apparatus. In one embodiment, the signal boosting apparatus may include a substrate, an oxide layer, and a signal transmission layer. The substrate may have a doped region where there are conductive carriers whose polarities are equal to a polarity related with an electronic signal. The oxide layer is located on the substrate. The signal transmission layer is located on the oxide layer, and is configured to receive and boost the electronic signal.

According to one or more embodiments, the disclosure also provides a method of boosting signals, adapted to a micro-electromechanical apparatus. In one embodiment, the method may include the following steps. First, dope impurity atoms into a doped region of a substrate where there may be conductive carriers whose polarities are equal to a polarity related with an electronic signal. Then, form an oxide layer on the substrate, and on the oxide layer, form a signal transmission layer for receiving and boosting the electronic signal.

The disclosure dopes impurity atoms in the doped region of the substrate to make the polarities of the conductive carriers in the doped region equal to the polarity related with the electronic signal in the signal transmission layer, so repulsion may occur between the substrate and the signal transmission layer. Therefore, the electronic signal may be prevented from the signal loss, to enhance the intensity of the electronic signal to increase the output power of the electronic signal, and the signal processing circuits may also be simplified.

### BRIEF DESCRIPTION OF THE DRAWINGS

The present disclosure will become more fully understood from the detailed description given herein below for illustration only, and thus does not limit the present disclosure, wherein:

FIG. 1A is a schematic view of a signal boosting apparatus in the disclosure;

FIG. 1B is a schematic view of a parasitic equivalence circuit in FIG. 1A; and

FIG. 2 is a flow chart of a method of boosting signals in the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

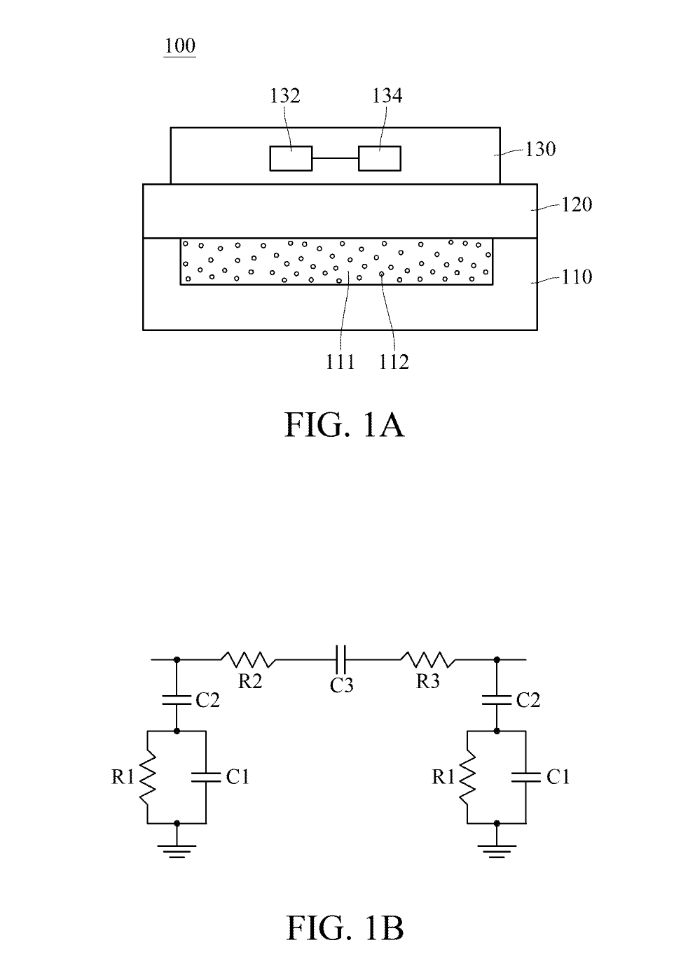

FIG. 1A is a schematic view of a signal boosting apparatus 100 in the disclosure. The signal boosting apparatus 100 may be adapted to a micro-electromechanical apparatus such as a microphone, a pressure sensor, an altimeter, a flowmeter, or a tactile sensor. That is, the signal boosting apparatus 100 may be implemented in the structure of the micro-electromechanical apparatus. The signal boosting apparatus 100 may include a substrate 110, an oxide layer 120, and a signal transmission layer 130.

The substrate 110 may have a doped region 111 where there are conductive carriers whose polarities are equal to the polarity related with an electronic signal. In the doped region 111, there are impurity atoms 112 which belong to, for example, Group 5 or Group 3. These conductive carriers may be electrons or holes. In one embodiment, while the doped impurity atoms 112 in the doped region 111 belong to Group 3, these conductive carriers are holes; and alternately, while the doped impurity atoms 112 in the doped region 111 belong to Group 5, these conductive carriers are electrons. For example, the substrate 110 may be a P type or N type silicon substrate.

The oxide layer 120 may be located on the substrate 110. In one embodiment, the oxide layer 120 may be formed through the thin film deposition. The signal transmission layer 130 may be located on the oxide layer 120 and be capable of receiving and boosting the electronic signal.

The signal transmission layer 130 may include a mass block 132 and a plurality of cantilevers 134 coupled with the mass block 132. The electronic signal may be transmitted from the mass block 132 to the cantilevers 134. For example, the mass block 132 may be made of polycrystalline silicon or another possible material with a small thermal expansion coefficient, and the cantilever 134 may be metallic or metalloid.

Take the Group 5 element as the impurity atoms 112. The impurity atoms 112 may be doped in the doped region 111 via an ion implanter or an impurity diffuser, but the disclosure will not be limited thereto, Since the impurity atoms 112 belonging to Group 5 present the attribute of electrons, the conductive carriers in the doped region 111 are electrons whose polarities are negative. In this equivalent circuit, when the electronic signal carrying negative charges flows in the signal transmission layer 130, since repulsion may occur between the electronic signal and the substrate 110, the electronic signal may only be transmitted through the signal transmission layer 130.

Accordingly, via the design of the doped region 111 of the signal boosting apparatus 100, the oxide layer 120 between the substrate 110 and the signal transmission layer 130 may be prevented from forming parasitic capacitors, to prevent the electronic signal from the signal loss flowing toward the substrate 110, so that the intensity of the electronic signal may be enhanced or maintained.

Referring to FIG. 1B, a parasitic equivalence circuit in FIG. 1A is shown. The substrate 110 may be equivalently determined as a parasitic resistor R1 and a parasitic capacitor C1. The oxide layer 120 may be equivalently determined as a parasitic capacitor C2. The signal transmission layer 130 may be equivalently determined as a parasitic resistor R2, a parasitic resistor R3, and a parasitic capacitor C3. Specifically, the parasitic resistor R2 may be formed based on the mass block 132, and the parasitic resistor R3 may be formed based on the cantilevers 134. The connection between each of the parasitic resistors R1, R2 and R3 and each of the parasitic capacitors C1, C2 and C3 may be referred to what is shown in FIG. 1B, and thus will not be repeated hereinafter.

Accordingly, for the signal boosting apparatus 100, since the electronic signal may be transmitted in the signal transmission layer 130, the electronic signal may be prevented from flowing toward the substrate 110. In other words, the electronic signal may be transmitted to the output end through the parasitic resistor R2, the parasitic capacitor C3, and the parasitic resistor R3 rather than through the parasitic capacitor C2, the parasitic resistor R1, and the parasitic capacitor C1. In this way, the electronic signal may be prevented from the signal loss, so that the intensity and output power of the electronic signal may be maintained or enhanced.

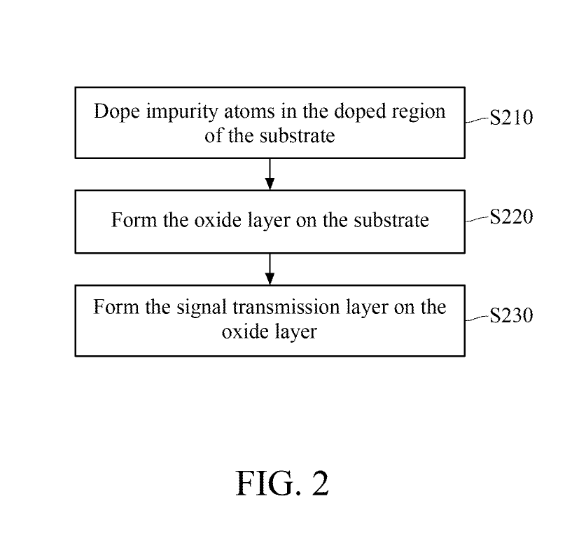

FIG. 2 is a flow chart of a method of boosting signals in the disclosure. Take a silicon substrate as the substrate 110. First, as shown in step S210, dope the impurity atoms 112 in the doped region 111 of the substrate 110. In one embodiment, the impurity atoms 112 may be doped into the substrate 110 via a doping apparatus such as an ion implanter or an impurity diffuser, but the disclosure will not be limited thereto.

In this case, in doped region 111, there are conductive carriers whose polarities are equal to the polarity related with the electronic signal. The doped impurity atoms 112 may belong to Group 5 or Group 3, and thus, the conductive carriers may be electrons or holes. That is, while the doped impurity atoms 112 belong to Group 3, the conductive carriers are holes, and while the doped impurity atoms 112 belong to Group 5, the conductive carriers are electrons.

Then, as shown in step S220, form the oxide layer 120 on the substrate 110. In one embodiment, the oxide layer 120 may be formed through the thin film deposition. Finally, on the oxide layer 120, form the signal transmission layer 130 for receiving and boosting the electronic signal (step S230). This signal transmission layer 130 may include the mass block 132 and the cantilevers 134 coupled with the mass block 132, and thus, the electronic signal may be transmitted to the cantilevers 134 through the mass block 132. For example, the mass block 132 may be made of polycrystalline silicon or other possible material with a small thermal expansion coefficient, and the cantilever 134 may be metallic or metalloid.

Accordingly, the method may prevent the oxide layer 120 between the substrate 110 and the signal transmission layer 130 from parasitic capacitors, to prevent the electronic signal from the signal loss flowing toward the substrate 110, to enhance or maintain the intensity of the electronic signal.

As set forth above, the disclosure, providing the signal boosting apparatus and the method of boosting signals, may dope impurity atoms in the doped region of the substrate to make the polarities of the conductive carriers in the doped region equal to the polarity related with the electronic signal in the signal transmission layer, so repulsion may occur between the substrate and the signal transmission layer. Therefore, the electronic signal may be prevented from the signal loss, to enhance the intensity of the electronic signal to increase the output power of the electronic signal, and the signal processing circuits may also be simplified.

What is claimed is:

1. A signal boosting apparatus, adapted to a micro-electromechanical apparatus and comprising:
a substrate, having a doped region where there are conductive carriers whose polarities are equal to a polarity related with an electronic signal;
an oxide layer, located on the substrate; and
a signal transmission layer, located on the oxide layer, and configured to receive and boost the electronic signal.

2. The signal boosting apparatus according to claim 1, wherein the signal transmission layer comprises a mass block and a plurality of cantilevers, the plurality of cantilevers is coupled with the mass block, and the electronic signal is transmitted from the mass block to the plurality of cantilevers.

3. The signal boosting apparatus according to claim 2, wherein the mass block contains polycrystalline silicon, and the plurality of cantilevers is metallic.

4. The signal boosting apparatus according to claim 1, wherein in the doped region there are doped impurity atoms which belong to Group 5 or Group 3.

5. The signal boosting apparatus according to claim 1, wherein the conductive carriers are electrons or holes.

6. A method of boosting signals, adapted to a micro-electromechanical apparatus and comprising:
doping impurity atoms into a doped region of a substrate, wherein in the doped region there are conductive carriers whose polarities are equal to a polarity related with an electronic signal;
forming an oxide layer on the substrate; and
forming a signal transmission layer for receiving and boosting the electronic signal, on the oxide layer.

7. The method according to claim 6, wherein the signal transmission layer comprises a mass block and a plurality of cantilevers, the plurality of cantilevers is coupled with the mass block, and the electronic signal is transmitted from the mass block to the plurality of cantilevers.

8. The method according to claim 7, wherein the mass block contains polycrystalline-silicon, and the plurality of cantilevers is metallic.

9. The method according to claim 6, wherein the doped impurity atoms belong to Group 5 or Group 3.

10. The method according to claim 6, wherein the conductive carriers are electrons or holes.
